(19) United States
(12) Patent Application Publication
(10) Pub. No.: US 2026/0287646 A1
(43) Pub. Date: Sep. 24, 2026

(54) HEAT DISSIPATION DEVICE AND HEAT DISSIPATION METHOD FOR TESTING EQUIPMENT

(71) Applicant: SILICONWARE PRECISION INDUSTRIES CO., LTD., Taichung City (TW)

(72) Inventors: Hsi-Chih CHEN, Taichung City (TW); Ming-Jen LIN, Taichung City (TW); Hsun-Yung CHO, Taichung City (TW); Ling Fei CHENG, Taichung City (TW); Chun-Sung HUANG, Taichung City (TW)

(73) Assignee: SILICONWARE PRECISION INDUSTRIES CO., LTD., Taichung City (TW)

(21) Appl. No.: 19/213,752

(22) Filed: May 20, 2025

(30) Foreign Application Priority Data
Mar. 19, 2025 (TW) 114110305

(51) Int. Cl. G01R 31/28

(52) U.S. Cl. CPC G01R 31/2877

(57) ABSTRACT

Provided are a heat dissipation device and a heat dissipation method for a testing equipment. The heat dissipation device includes a heat dissipation structure and a flow-directing set. The heat dissipation structure is disposed on a testing machine of the testing equipment. The flow-directing set is connected to the heat dissipation structure and includes a flow-directing unit and a temperature controller for controlling the flow-directing unit. The flow-directing unit is configured to direct airflow to pass through the heat dissipation structure, and the temperature controller is configured to measure a real-time temperature of the testing machine to activate a suction operation of the flow-directing unit according to the real-time temperature, thereby the heat dissipation method for the testing equipment is to dissipate heat from the testing machine via the heat dissipation device.

### BACKGROUND

### 1. Technical Field

The present disclosure relates to a semiconductor package testing technology, and more particularly, to a heat dissipation device and a heat dissipation method for a testing equipment.

### 2. Description of Related Art

With the vigorous development of portable electronic products in recent years, the development of various related products is also moving towards high density, high performance, light, thin, short, and small. To this end, the industry has developed various integrated multifunctional packaging forms in order to meet the requirements of electronic products being thin, light, short, small, and high-density. Therefore, the testing equipment for various consumer electronic products also needs to be designed in accordance with product requirements.

FIG. 1A is a partial three-dimensional schematic view of a conventional testing equipment 1. FIG. 1B is a partial side cross-sectional schematic view of the conventional testing equipment 1.

As shown in FIG. 1A and FIG. 1B, the testing equipment 1 is an electrical testing equipment, wherein the testing equipment 1 includes a working platform 1a, a circuit base 90 disposed on the working platform 1a, a test socket 91 disposed on the circuit base 90, a moving base 92 disposed above the test socket 91, and a high-speed input and output (HSIO) element 93 disposed on the circuit base 90.

The circuit base 90 has a large rectangular layout (e.g., the circuit base 90 is a large rectangular board), and the required circuits (not shown) are arranged inside the circuit base 90 to transmit the testing data or other information to the computer (not shown).

The test socket 91 is electrically connected to the circuit base 90 and has at least one groove for placing a target test object 8 so as to facilitate positioning of the target test object 8. A plurality of probes 910 such as spring pins are disposed in the groove to contact the target test object 8, wherein the target test object 8 is an electronic package equipped with a semiconductor chip.

The moving base 92 is a robotic arm or other displaceable holding mechanism, and is used to displace the target test object 8 to a desired position.

The high-speed input and output element 93 is electrically connected to the circuit base 90 for operation in conjunction with the circuit base 90.

However, the conventional testing equipment 1 does not have a heat dissipation mechanism. Therefore, heat is easily accumulated in the central region of the circuit base 90, thereby causing the internal circuits of the circuit base 90 or the elements thereon (such as the high-speed input and output element 93) to be easily damaged due to overheating.

Therefore, how to overcome the above-mentioned drawbacks of the prior art has become an urgent issue to be solved.

### SUMMARY

In view of the various deficiencies of the prior art, the present disclosure provides a heat dissipation device for a testing equipment, and the heat dissipation device comprises: a heat dissipation structure disposed on a testing machine of the testing equipment; and a flow-directing set connected to the heat dissipation structure and including a flow-directing unit and a temperature controller for controlling the flow-directing unit, wherein the flow-directing unit is configured to direct airflow to pass through the heat dissipation structure, and the temperature controller is configured to measure a real-time temperature of the testing machine to activate a suction operation of the flow-directing unit according to the real-time temperature.

The present disclosure also provides a heat dissipation method for a testing equipment, and the heat dissipation method comprises: positioning a target test object on a testing machine of the testing equipment, wherein the testing equipment further comprises the aforementioned heat dissipation device; monitoring, by the temperature controller, a real-time temperature of the testing machine, wherein the heat dissipation structure dissipates heat from the testing machine; and activating, by the temperature controller, a suction operation of the flow-directing unit when the real-time temperature obtained by the temperature controller is greater than or equal to a reference temperature.

In the aforementioned heat dissipation device and heat dissipation method, the heat dissipation structure comprises at least one guide tube having a plurality of first holes, and the flow-directing unit supplies airflow via the plurality of first holes to blow toward the testing machine to dissipate heat from the testing machine.

In the aforementioned heat dissipation device and heat dissipation method, the heat dissipation structure comprises at least one guide tube having a plurality of second holes, and the suction operation of the flow-directing unit directs airflow to pass through the plurality of second holes.

In the aforementioned heat dissipation device and heat dissipation method, the heat dissipation structure comprises at least one suction portion having a plurality of air holes, and the suction operation of the flow-directing unit directs airflow to pass through the plurality of air holes.

In the aforementioned heat dissipation device and heat dissipation method, the heat dissipation structure comprises a frame and a plurality of guide tubes disposed on the frame.

In the aforementioned heat dissipation device and heat dissipation method, the frame has an opening corresponding to the testing equipment, some of the plurality of guide tubes are mounted on the opening, and the other of the plurality of guide tubes are arranged along edges of the opening.

In the aforementioned heat dissipation device and heat dissipation method, the temperature controller measures fixed-point temperatures of various locations on the testing machine and converts the fixed-point temperatures into an average temperature to be used as the real-time temperature.

In the aforementioned heat dissipation device and heat dissipation method, the reference temperature is 55° C., and the temperature controller activates the suction operation of the flow-directing unit when the real-time temperature is greater than or equal to 55° C.

In the aforementioned heat dissipation device and heat dissipation method, the temperature controller stops the suction operation of the flow-directing unit according to the real-time temperature, and the temperature controller stops the suction operation of the flow-directing unit when the real-time temperature is less than the reference temperature. For example, the reference temperature is 55° C., and the temperature controller stops the suction operation of the flow-directing unit when the real-time temperature is less than 55° C.

As can be seen from the above, in the heat dissipation device and the heat dissipation method of the present disclosure, the temperature controller measures the real-time temperature of the testing machine to activate the suction operation of the flow-directing unit according to the real-time temperature. Therefore, compared with the prior art, the heat dissipation structure of the heat dissipation device of the present disclosure is disposed on the testing machine to dissipate heat from the testing machine. Accordingly, the testing machine is less likely to accumulate heat, effectively preventing overheating-related damage to internal circuits of the testing machine or elements thereon.

### BRIEF DESCRIPTION OF THE DRAWINGS

FIG. 1A is a partial three-dimensional schematic view of a conventional testing equipment.

FIG. 1B is a partial side cross-sectional schematic view of the conventional testing equipment.

FIG. 2A is a partial three-dimensional schematic view of a heat dissipation device according to the present disclosure applied to a testing equipment.

FIG. 2B is a three-dimensional schematic view of the heat dissipation device according to the present disclosure.

FIG. 3A to FIG. 3D are schematic views illustrating a heat dissipation method of the heat dissipation device according to the present disclosure.

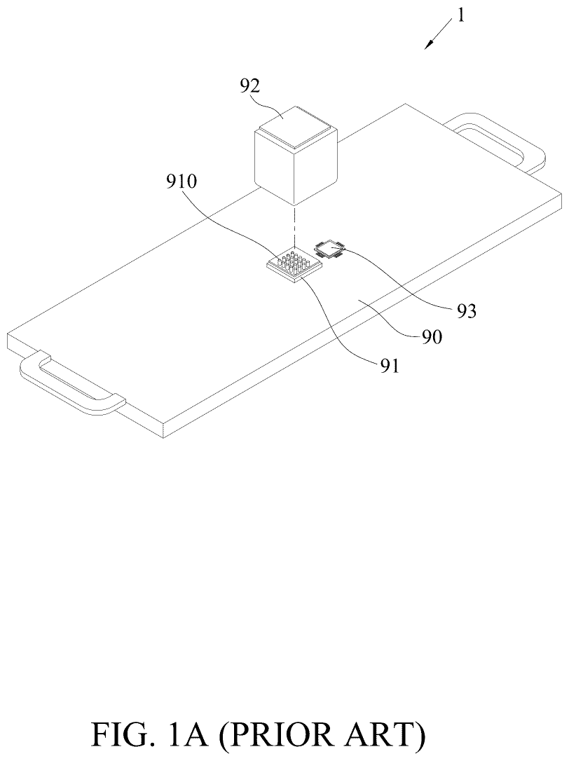

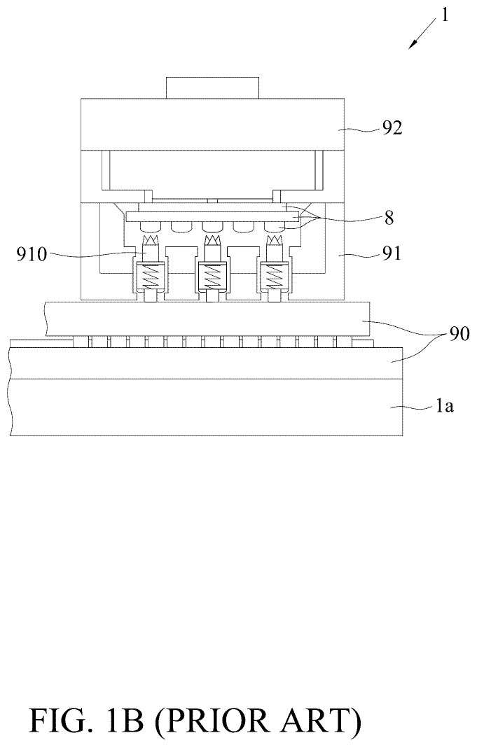

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “above,” “on,” “first,” “second,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

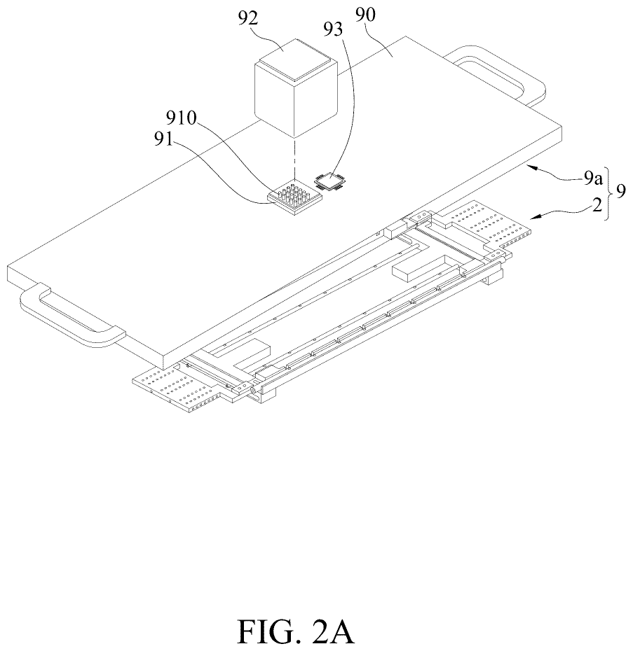

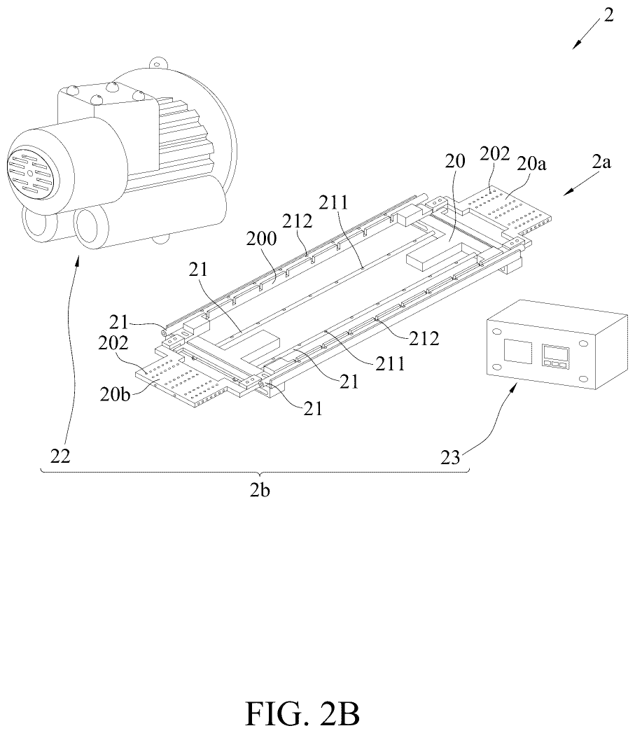

FIG. 2A is a partial three-dimensional schematic view of a heat dissipation device 2 according to the present disclosure applied to a testing equipment 9. FIG. 2B is a three-dimensional schematic view of the heat dissipation device 2 according to the present disclosure.

As shown in FIG. 2A, the testing equipment 9 is an electrical testing equipment, and the testing equipment 9 comprises a testing machine 9a and a heat dissipation device 2 disposed on the testing machine 9a.

In one embodiment, the testing machine 9a includes a working platform (not shown), a circuit base 90 disposed on the working platform, a test socket 91 disposed on the circuit base 90, a moving base 92 disposed above the test socket 91, and a high-speed input and output element 93 disposed on the circuit base 90.

The circuit base 90 has a large rectangular layout (e.g., the circuit base 90 is a large rectangular board), and the required circuits (not shown) are arranged inside the circuit base 90 to transmit the testing data or other information to the computer (not shown).

The test socket 91 is electrically connected to the circuit base 90 and has at least one groove for placing a target test object (not shown) to facilitate positioning of the target test object. A plurality of probes 910 such as spring pins are disposed in the groove to contact the target test object, wherein the target test object is an electronic package or electronic element equipped with a semiconductor chip.

The moving base 92 is a robotic arm or other displaceable holding mechanism, and is used to displace the target test object to a desired position.

The high-speed input and output element 93 is electrically connected to the circuit base 90 for operation in conjunction with the circuit base 90.

As shown in FIG. 2B, the heat dissipation device 2 comprises a heat dissipation structure 2a disposed at the bottom of the testing machine 9a (or the circuit base 90) and a flow-directing set 2b connected to the heat dissipation structure 2a.

In one embodiment, the heat dissipation structure 2a includes a frame 20 and a plurality of (e.g., four) guide tubes 21 disposed on the frame 20.

The frame 20 is generally rectangular in shape and has an opening 200 corresponding to the circuit base 90. The frame 20 is provided with suction portions 20a, 20b like wings on opposite sides of the opening 200, and a plurality of air holes 202 arranged in an array are formed on the suction portions 20a, 20b.

The guide tubes 21 span across opposite sides of the frame 20. Some (e.g., two) of the guide tubes 21 are mounted on the opening 200 to separate the opening 200 into a plurality of regions of equal area, while the other (e.g., two) of the guide tubes 21 are arranged along the edges of the opening 200, wherein a plurality of first holes 211 are formed on the surface of each of the guide tubes 21 on the opening 200, and a plurality of second holes 212 are formed on the surface of each of the guide tubes 21 at the edges of the opening 200.

Moreover, the flow-directing set 2b includes a flow-directing unit 22 (e.g., a flow-directing host) and a temperature controller 23 for controlling the flow-directing unit 22.

The flow-directing unit 22 directs air to flow into the heat dissipation structure 2a and its surroundings so as to guide the airflow to pass through the air holes 202, the first holes 211, and the second holes 212. In one embodiment, the flow-directing unit 22 is an air blower.

The temperature controller 23 measures a real-time temperature of the circuit base 90 of the testing machine 9a so as to activate or stop the operation of the flow-directing unit 22 according to the real-time temperature of the circuit base 90 of the testing machine 9a.

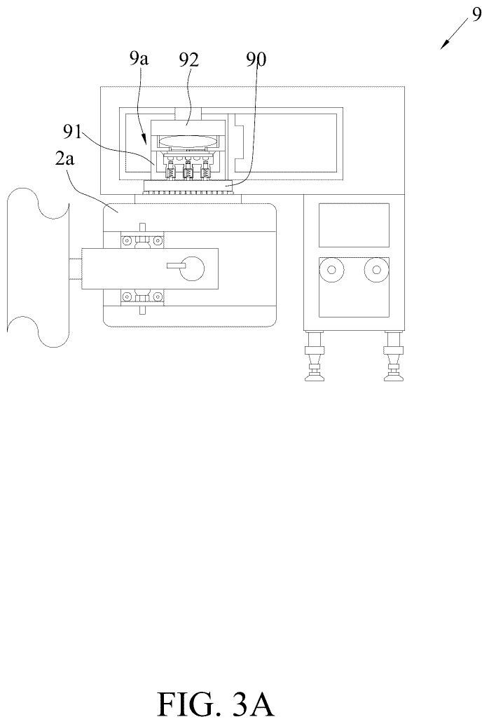

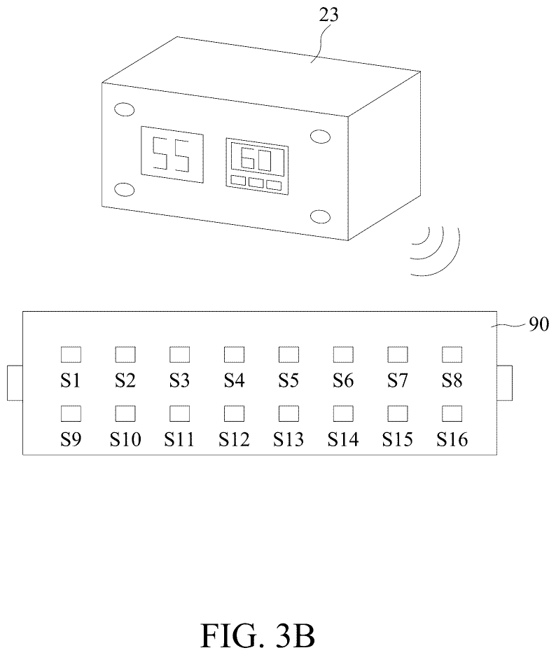

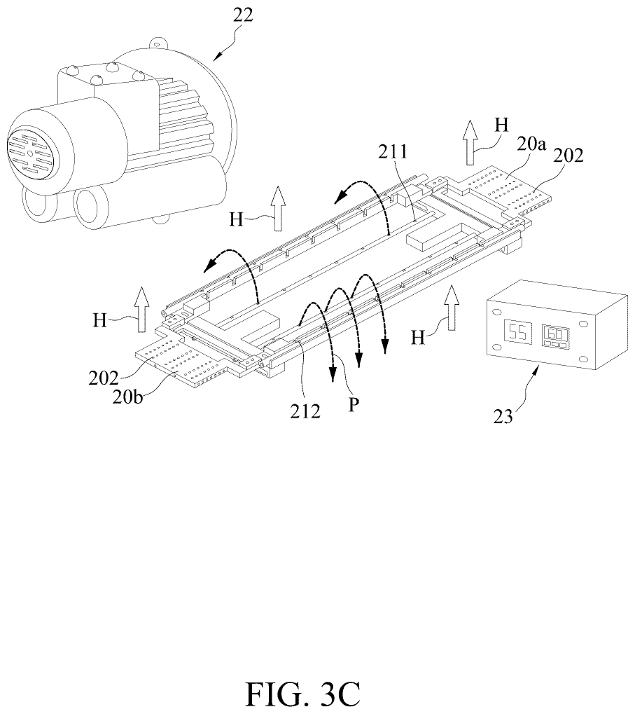

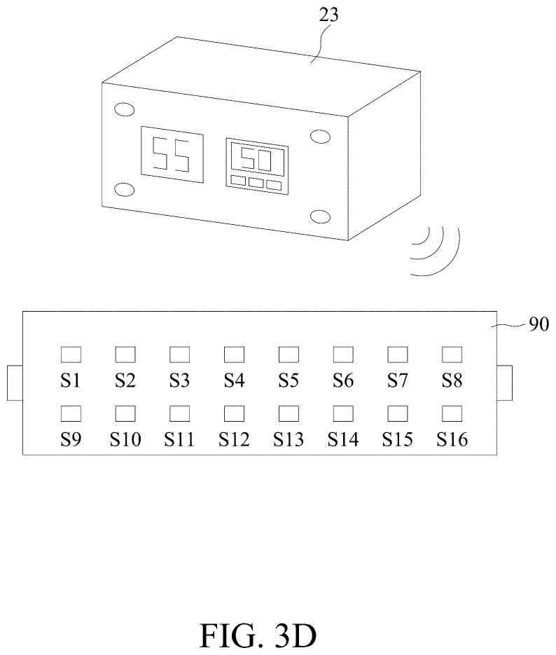

FIG. 3A to FIG. 3D illustrate an operation process of the heat dissipation device 2 according to the present disclosure.

As shown in FIG. 3A, the target test object (not shown) is positioned in the groove of the test socket 91, which is disposed on the circuit base 90, by the moving base 92, so that testing on the target test object can begin.

As shown in FIG. 3B, during the testing process, the temperature controller 23 starts to monitor the real-time temperature of the circuit base 90 of the testing machine 9a, and the heat dissipation structure 2a dissipates heat from the testing machine 9a.

In one embodiment, the flow-directing unit 22 supplies airflow or blows cool air, directing the airflow through the first holes 211 of the guide tubes 21 toward the bottom of the circuit base 90 of the testing machine 9a (in a direction of arrow P as shown in FIG. 3C). This process helps dissipate the heat generated by the circuit base 90 of the testing machine 9a, allowing hot air to disperse into the surroundings for cooling. For example, the airflow volume through each of the first holes 211 is equal.

Furthermore, the temperature controller 23 measures fixed-point temperatures at various locations on the bottom of the circuit base 90 of the testing machine 9a, and then converts the fixed-point temperatures into an average temperature to be used as a real-time temperature to determine whether the average temperature reaches or exceeds a reference temperature. For example, the bottom of the circuit base 90 can be divided into sixteen regions S1 to S16 in an array. Thus, the temperature controller 23 measures the fixed-point temperatures of the sixteen regions S1 to S16 at the bottom of the circuit base 90 and converts them into an average temperature as the real-time temperature, and the reference temperature is set to 55° C.

As shown in FIG. 3C, when the real-time temperature obtained by the temperature controller 23 (60° C. as shown in FIG. 3B) is greater than or equal to the reference temperature (55° C.), it indicates that the heat dissipation of the circuit base 90 of the testing machine 9a is slow. Therefore, the temperature controller 23 activates a suction operation of the flow-directing unit 22 (e.g., a suction action of the flow-directing unit 22) to increase the cooling rate.

In one embodiment, the suction operation of the flow-directing unit 22 draws in the dissipated hot air surrounding the circuit base 90 of the testing machine 9a via the air holes 202 of the suction portions 20a, 20b and the second holes 212 of the guide tubes 21 (as shown in a direction of arrow H in FIG. 3C). The hot air is then directed to the flow-directing unit 22 for discharge. For example, the airflow volume through each of the second holes 212 is equal to the airflow volume through each of the air holes 202.

As shown in FIG. 3D, the temperature controller 23 automatically stops the suction operation of the flow-directing unit 22 when the real-time temperature (the average temperature) obtained by the temperature controller 23 is lower than the reference temperature (55° C.).

In one embodiment, the flow-directing set 2b adopts an automated control design for application in the cooling mechanism of a compressed dry air (CDA) system. Therefore, recovered waste heat in the form of warm water can be utilized for pre-cooling operations in other semiconductor packaging processes, reducing chilled water consumption and achieving energy savings, thereby meeting energy efficiency requirements.

Therefore, in the heat dissipation device 2 and the heat dissipation method of the present disclosure, the temperature controller 23 measures the real-time temperature of the testing machine 9a to activate the suction operation of the flow-directing unit 22 according to the real-time temperature. Therefore, compared with the prior art, the heat dissipation structure 2a of the heat dissipation device 2 of the present disclosure is disposed at the bottom of the testing machine 9a (or the circuit base 90) to dissipate heat from the testing machine 9a (or the circuit base 90). Accordingly, the testing machine 9a (or the circuit base 90) is less likely to accumulate heat, effectively preventing overheating-related damage to internal circuits of the testing machine 9a (or the circuit base 90) or elements thereon (such as the high-speed input and output element 93).

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A heat dissipation device for a testing equipment, comprising:
a heat dissipation structure disposed on a testing machine of the testing equipment; and
a flow-directing set connected to the heat dissipation structure and including a flow-directing unit and a temperature controller for controlling the flow-directing unit, wherein the flow-directing unit is configured to direct airflow to pass through the heat dissipation structure, and the temperature controller is configured to measure a real-time temperature of the testing machine to activate a suction operation of the flow-directing unit according to the real-time temperature.

2. The heat dissipation device of claim 1, wherein the heat dissipation structure comprises at least one guide tube having a plurality of first holes, and the flow-directing unit supplies airflow via the plurality of first holes to blow toward the testing machine to dissipate heat from the testing machine.

3. The heat dissipation device of claim 1, wherein the heat dissipation structure comprises at least one guide tube having a plurality of second holes, and the suction operation of the flow-directing unit directs airflow to pass through the plurality of second holes.

4. The heat dissipation device of claim 1, wherein the heat dissipation structure comprises at least one suction portion having a plurality of air holes, and the suction operation of the flow-directing unit directs airflow to pass through the plurality of air holes.

5. The heat dissipation device of claim 1, wherein the heat dissipation structure comprises a frame and a plurality of guide tubes disposed on the frame.

6. The heat dissipation device of claim 5, wherein the frame has an opening corresponding to the testing equipment, some of the plurality of guide tubes are mounted on the opening, and the other of the plurality of guide tubes are arranged along edges of the opening.

7. The heat dissipation device of claim 1, wherein the temperature controller measures fixed-point temperatures of various locations on the testing machine and converts the fixed-point temperatures into an average temperature to be used as the real-time temperature.

8. The heat dissipation device of claim 1, wherein the temperature controller activates the suction operation of the flow-directing unit when the real-time temperature is greater than or equal to 55° C.

9. The heat dissipation device of claim 1, wherein the temperature controller stops the suction operation of the flow-directing unit according to the real-time temperature.

10. The heat dissipation device of claim 9, wherein the temperature controller stops the suction operation of the flow-directing unit when the real-time temperature is less than 55° C.

11. A heat dissipation method for a testing equipment, comprising:
positioning a target test object on a testing machine of the testing equipment, wherein the testing equipment further comprises the heat dissipation device of claim 1;
monitoring, by the temperature controller, a real-time temperature of the testing machine, wherein the heat dissipation structure dissipates heat from the testing machine; and
activating, by the temperature controller, a suction operation of the flow-directing unit when the real-time temperature obtained by the temperature controller is greater than or equal to a reference temperature.

12. The heat dissipation method of claim 11, wherein the heat dissipation structure comprises at least one guide tube having a plurality of first holes, and the flow-directing unit supplies airflow via the plurality of first holes to blow toward the testing machine to dissipate heat from the testing machine.

13. The heat dissipation method of claim 11, wherein the heat dissipation structure comprises at least one guide tube having a plurality of second holes, and the suction operation of the flow-directing unit directs airflow to pass through the plurality of second holes.

14. The heat dissipation method of claim 11, wherein the heat dissipation structure comprises at least one suction portion having a plurality of air holes, and the suction operation of the flow-directing unit directs airflow to pass through the plurality of air holes.

15. The heat dissipation method of claim 11, wherein the heat dissipation structure comprises a frame and a plurality of guide tubes disposed on the frame.

16. The heat dissipation method of claim 15, wherein the frame has an opening corresponding to the testing equipment, some of the plurality of guide tubes are mounted on the opening, and the other of the plurality of guide tubes are arranged along edges of the opening.

17. The heat dissipation method of claim 11, wherein the temperature controller measures fixed-point temperatures of various locations on the testing machine and converts the fixed-point temperatures into an average temperature to be used as the real-time temperature.

18. The heat dissipation method of claim 11, wherein the reference temperature is 55° C.

19. The heat dissipation method of claim 11, further comprising: stopping, by the temperature controller, the suction operation of the flow-directing unit when the real-time temperature is less than the reference temperature.

20. The heat dissipation method of claim 19, wherein the reference temperature is 55°C.
